(19) United States
(12) Patent Application Publication
(10) Pub. No.: US 2009/0269492 A1
(43) Pub. Date: Oct. 29, 2009

(54) Apparatus and Method for Deposition Organic Compounds, and Substrate Treating Facility With the Apparatus

(76) Inventors: Il-Ho No, Gyeongg-do (KR); Suk--Min Choi, Gyeonggi-do (KR); Young-Chul Joung, Gyeonggi-do (KR)

Correspondence Address: HARNESS, DICKEY & PIERCE, P.L.C., P.O. BOX 8910, RESTON, VA, 20195, US

(21) Appl. No.: 12/084,624

(22) PCT Filed: Nov. 2, 2006
(86) PCT No.: PCT/KR2006/004534

§ 371 Date: Aug. 4, 2008

(30) Foreign Application Priority Data
Nov. 7, 2005 (KR) 10-2005-0106023

(51) Int. Cl. C23C 16/44; C23C 16/54

(52) U.S. Cl. 427/255.6; 118/726

(57) ABSTRACT

An apparatus for depositing organic compounds is provided to deposit predetermined organic films on a substrate. The apparatus includes a deposition chamber, a support member provided inside the deposition chamber and supporting the substrate to make a deposition surface of the substrate face downwardly, a vaporizer installing portion in which an organic vaporizer is installed to vaporize organic compounds to the deposition surface of the substrate, and a vaporizer replacing portion disposed adjacent to the vaporizer installing portion to replace the organic vaporizer. According to the apparatus, organic vaporizers for vaporizing organic compounds are replaced automatically.

### TECHNICAL FIELD

The present invention is directed to apparatus and method for depositing organic compounds to form organic thin films on a substrate and a substrate treating system with the apparatus.

### BACKGROUND ART

Organic light emitting diodes (OLEDs) are active light emitting displays that have a wide viewing angle, a superior contrast ratio, and a high responsive speed. Thus, OLEDs are increasingly attractive as next-generation flat panel displays which will replace liquid crystal displays (LCDs).

In the conventional field of OLEDs, organic compounds are vaporized and deposited to form thin films on a substrate Surface. The above deposition process is performed to form organic thin films and metal electrode layers used in, for example, an OLED light emitting layer of an OLED display panel.

A conventional apparatus for depositing organic compounds includes a deposition chamber and an organic vaporizer. The deposition chamber is provided to define a space in which an organic compound is deposited on a substrate Surface. The organic vaporizer heats the organic compound to vaporize the same to the substrate Surface.

The organic vaporizer includes a predetermined crucible that is provided inside a vacuum deposition room and exhibits excellent heatproof and excellent chemical stability. Hot wires are provided to an inner or outer sidewall of the crucible for heating and vaporizing predetermined organic compounds stored in the crucible.

When the organic vaporizer vaporizes all organic compounds, it is necessary to fill the organic vaporizer with organic compounds or replace the organic vaporizer with a new organic vaporizer. Conventionally, filling an organic vaporizer with organic compounds is done by operator's hand(s). Therefore, an operator suffers from high-cost maintenance fees and a deposition process using an apparatus for depositing organic compounds is not performed during maintaining the organic vaporizer.

### DISCLOSURE OF INVENTION

### Technical Problem

Exemplary embodiments of the present invention are directed to apparatus and method for depositing organic compounds on a substrate and a substrate treating system with the apparatus, the apparatus including an organic vaporizer replaced automatically or without crease of an organic compound deposition process.

### Technical Solution

In an exemplary embodiment, an apparatus for depositing organic compounds may include a deposition chamber; a support member provided inside the deposition chamber and supporting the substrate to make a deposition surface of the substrate face downwardly; a vaporizer installing portion in which an organic vaporizer is installed to vaporize organic compounds to the deposition surface of the substrate; and a vaporizer replacing portion disposed adjacent to the vaporizer installing portion to replace the organic vaporizer.

According to the embodiment of the present invention, the apparatus may include a vaporizer transporting unit configured to transport the organic vaporizer between the vaporizer installing portion and the vaporizer replacing portion.

According to the embodiment of the present invention, the vaporizer transporting unit may include a guide member configured to guide the movement of the organic vaporizer; and a driver for allowing the organic vaporizer to move along the guide member.

According to the embodiment of the present invention, the vaporizer transporting unit may include a sensoring portion configured to measure the consumption of organic compounds in the organic vaporizer; and a controller receiving data from the sensoring portion to determine replacement timing of the organic vaporizer and controlling the vaporizer transporting unit to replace the organic vaporizer.

According to the embodiment of the present invention, the vaporizer replacing portion may include a standby chamber, disposed at one side of the vaporizer installing portion, in which a new organic vaporizer waits; and a take-out chamber, disposed the other side of the vaporizer installing portion, of which the organic vaporizer replaced with the new organic vaporizer is taken out.

According to the embodiment of the present invention, the standby chamber comprises a first shutting member configured to open and close an inlet through which the organic vaporizer is carried into the deposition chamber from the standby chamber, and the take-out chamber comprises a second shutting member configured to open and close an outlet through which the organic vaporizer is taken out of the deposition chamber into the take-out chamber.

In an exemplary embodiment, the method for depositing organic compounds may include measuring the amount of organic compounds stored in an organic vaporizer when a deposition process is carried out to deposit organic compounds on a substrate; and replacing the organic vaporizer with a new organic vaporizer if the amount of the organic compounds stored in the organic vaporizer is smaller than a preset amount of organic compounds, wherein the replacing the organic vaporizer with a new organic vaporizer includes taking out the organic vaporizer to a vaporizer installing portion from a deposition chamber; and carrying the new organic vaporizer into the deposition chamber from the vaporizer installing portion.

According to the embodiment of the present invention, the replacing the organic vaporizer is done by taking out the organic vaporizer to a take-out chamber disposed adjacent to the deposition chamber and carrying the new organic chamber into the deposition chamber from a standby chamber in which the new organic vaporizer waits.

According to the embodiment of the present invention, the vaporizer installing portion includes a take-out chamber of which the organic vaporizer is taken out from the deposition chamber and a standby chamber in which a new organic vaporizer waits before entering the deposition chamber, the replacing the organic vaporizer includes the step of taking out the organic vaporizer to the take-out chamber from the deposition chamber and the step of carrying the new organic chamber into the deposition chamber from a standby chamber.

According to the embodiment of the present invention, the taking out the organic vaporizer to the take-out chamber from the deposition chamber comprises adjusting an inner pressure of the take-out chamber to be same as a process pressure of the deposition chamber; opening the first shutting member configured to open and close an outlet through which the organic vaporizer is transported between the deposition chamber and the take-out chamber; transporting the organic vaporizer to the take-out chamber from the deposition chamber; and closing the first shutting member.

According to the embodiment of the present invention, the carrying the organic vaporizer into the deposition chamber from the standby chamber comprises: adjusting an inner pressure of the standby chamber to be same as a process pressure of the deposition chamber; opening the second shutting member configured to open and close an inlet through which the organic vaporizer is transported between the standby chamber and the deposition chamber; transporting the organic vaporizer to the deposition chamber from the standby chamber; and closing the second shutting member.

According to the embodiment of the present invention, the taking out the organic vaporizer to the take-out chamber from the deposition chamber further comprises dropping the inner pressure of the take-out chamber to the process pressure of the deposition chamber when the organic vaporizer is drawn to the exterior of the take-out chamber.

According to the embodiment of the present invention, the carrying the organic vaporizer into the deposition chamber from the standby chamber comprises putting the organic vaporizer or another organic vaporizer into the standby chamber; and dropping the inner pressure of the standby chamber to a process pressure of the deposition chamber.

According to the embodiment of the present invention, the measuring the amount of organic compounds stored in the organic vaporizer is done by measuring weight change of the organic vaporizer.

In an exemplary embodiment, the substrate treating system may include a mask attaching apparatus configured to attach a pattern-formed mask to a deposition surface of a substrate; a deposition apparatus configured to deposit organic compounds on the mask-attached deposition surface of the substrate; and a mask recovering apparatus configured to recover the mask from the substrate on which the organic compounds are deposited, wherein the deposition apparatus includes a deposition chamber; a support member provided inside the deposition chamber and supporting the substrate to make a deposition surface of the substrate face downwardly; a vaporizer installing portion in which an organic vaporizer is installed to vaporize organic compounds to the deposition surface of the substrate; a vaporizer replacing portion disposed adjacent to the vaporizer installing portion to replace the organic vaporizer; and a vaporizer transporting unit configured to transport the organic vaporizer between the vaporizer installing portion and the vaporizer replacing portion.

According to the embodiment of the present invention, the vaporizer transporting unit further comprises a sensoring portion configured to measure the consumption of organic compounds of the organic vaporizer; and a controller receiving data from the sensoring portion to determine replacement timing of the organic vaporizer and controlling the vaporizer transporting unit to replace the organic vaporizer.

According to the embodiment of the present invention, the vaporizer replacing portion comprises a standby chamber, disposed at one side of the vaporizer installing portion, in which a new organic vaporizer waits; and a take-out chamber, disposed the other side of the vaporizer installing portion, of which the new organic vaporizer is taken out.

According to the embodiment of the present invention, the standby chamber comprises a first shutting member configured to open and close an inlet through which the organic vaporizer is carried into the deposition chamber from the standby chamber, and the take-out chamber comprises a second shutting member configured to open and close an outlet through which the organic vaporizer is taken out of the deposition chamber into the take-out chamber.

According to the embodiment of the present invention, the sensoring portion includes at least one load cell.

### Advantageous Effects

According to the present invention, an organic vaporizer is replaced automatically.

According to the present invention, an organic vaporizer is replaced without cease of an organic compound deposition process.

### BRIEF DESCRIPTION OF THE DRAWINGS

FIG. 1 is a perspective view of a substrate treating system with an apparatus for depositing organic compounds according to the present invention.

FIG. 2 is a configuration diagram of the apparatus for depositing organic compounds shown in FIG. 1.

FIG. 3 through FIG. 7 are diagram illustrating the operation and effect of the apparatus for depositing organic compounds shown in FIG. 2.

FIG. 8 is a flowchart illustrating a method for depositing organic compounds according to the present invention.

### DESCRIPTION OF THE NUMBER ABOUT THE ESSENTIAL PORTION OF THE DRAWINGS

100: deposition apparatus 110: deposition chamber

112: vaporizer installing portion 114: blocking plate

116a, 116b : substrate entrance and substrate exit

118: support member 122, 124: organic vaporizer

130: standby chamber 132: housing

134: first shutting member 136: first door

140: take-out chamber 142: housing

144: first shutting member 146: second door

150: vaporizer replacing portion 160: vaporizer transporting unit

162: guide member 164; driver

170: sensoring portion 180: controller

### BEST MODE FOR CARRYING OUT THE INVENTION

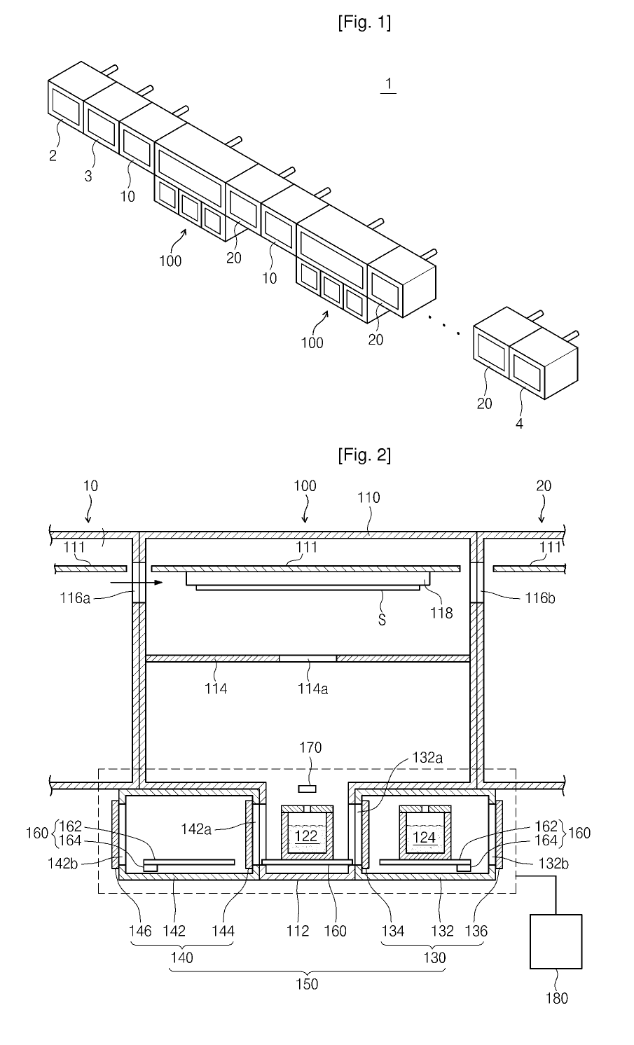

FIG. 1 is a perspective view of a substrate treating system with an apparatus for depositing organic compounds according to the present invention, and FIG. 2 is a configuration diagram of the apparatus shown in FIG. 1.

Referring to FIG. 1, a substrate treating system 1 includes a plurality apparatuses such as, for example, a loading apparatus 2, a cleaning apparatus 3, an unloading apparatus 4, a mask attach apparatus 10, a mask recovering apparatus 20, and a deposition apparatus 100 for depositing organic compounds. Since the deposition apparatus 100 is variable in number, each of the above-mentioned apparatuses is also variable in number.

A substrate S, on which a deposition process is to be performed, is carried in the substrate treating system 1 through the loading apparatus 2. After the deposition process is completed, the substrate S is taken out of the substrate treating system 1 through the unloading apparatus 4. The substrate S carried in the lading apparatus 2 is transferred to the cleaning apparatus 3. The cleaning apparatus 3 cleans the substrate S using plasma or ultraviolet rays. The cleaned substrate S is transferred to the mask attach apparatus 10, the deposition apparatus 100, and the mask recovering apparatus 20, in the order named. The mask attach apparatus 10 attaches a pattern-formed mask (not shown) onto the cleaned substrate S. The mask recovering apparatus 20 recovers a mask from the substrate S on which the deposition process is completed. The organic deposition apparatus 100 deposits organic compounds on a treating surface of a mask-attached substrate S.

Referring to FIG. 2, the deposition apparatus 100 includes a deposition chamber 110, organic vaporizers 122 and 124, a vaporizer replacing portion 150 with a standby chamber 130 and a take-out chamber 140, a vaporizer transporting unit 160, a sensoring portion 170, and a controller 180.

The deposition chamber 110 defines a space in which organic compounds are deposited on a surface of a substrate S. a vaporizer installing portion 112 is provided to a bottom wall of the deposition chamber 110. The organic vaporizer 122 may be installed in the vaporizer installing portion 112. The vaporizer proving portion 112 is a lower portion of the deposition chamber 110 in which the organic vaporizer 122 is loaded. The organic vaporizer 122 and the deposition chamber 110 may be manufactured individually before being coupled with each other. The inside of the deposition chamber 110 is sealed from the outside thereof and maintained at a vacuum state during a process.

The deposition chamber 110 comprises a blocking plate 114 disposed on the upper portion of the organic vaporizer 122. The blocking plate 114 is disposed on lower portion than a path through which the substrate travel. Therefore, the inside of the deposition chamber 110 is partitioned by a blocking plate 114 into an upper portion on which the substrate is transported and a lower portion on which the organic vaporizer 122 is provided. A opening 114a is formed on the blocking plate through which the organic compounds vaporized from the organic vaporizer 122 is deposited on the deposition surface of the substrate. The opening 114a allows the organic compounds to deposit on a specific region of the deposition surface of the substrate.

A support member 118 is provided to the upper portion of the deposition chamber 110. The support member 118 is transported between the outside and the inside of the deposition chamber 110 through substrate entrance 116a and substrate exit 116b. While organic compounds are deposited on a substrate S, the support member 118 moves the substrate S inside the deposition chamber 110 at a regular speed. Alternatively, the support member 118 may be fixed to a top side of the deposition chamber 110 to adsorb and support a substrate S transported into the deposition chamber 110 by a substrate transport unit. In an embodiment, the substrate transport unit includes a guide rail 111 configured to guide the travel of the support member 118 and a transfer unit (not shown) configured to transfer the support member 118 along the guide rail 111.

A mask attach chamber 10 and a mask recover chamber 20 are disposed adjacent to opposite sides of the deposition chamber 110, respectively. Inside the mask attach chamber 10, a pattern-formed mask (not shown) is attached to a substrate S. The mask-attached substrate S travels to the deposition chamber 110, depositing a thin film from a rear surface to a front surface of the substrate S. The substrate S, on which the thin film is deposited, travels into the mask recover chamber 20. Inside the mask recover chamber 20, the mask is removed from the substrate S. The attachment, deposition, and removal of the mask are repeatedly conducted to form a predetermined pattern on the substrate S.

The organic vaporizer 122 vaporize the organic compounds during the deposition process. The organic vaporizer 122 is disposed on a lower side within the chamber 110 to vaporize organic compounds during a deposition process. The organic vaporizer 122 is a kind of a container in which organic compounds are contained and vaporized. A vaporization hole is formed at the top of the container. Vaporized organic compounds are exhausted through the vaporization hole.

The organic vaporizer 124 has the same configuration as the organic vaporizer 122. The organic vaporizer 124 is replaced with the organic vaporizer 122 when use of the organic compounds contained in the organic vaporizer 122 is ended. Namely, the organic vaporizer 124 waits in the standby chamber 130 and, when use of the organic vaporizer 122 is ended and the deposition chamber 110 is taken out to the exterior, the organic vaporizer 124 is transported into the deposition chamber 110 to replace the organic vaporizer 122.

The vaporizer replacing portion 150 includes a standby chamber 130 and a take-out chamber 140. The standby chamber 130 includes a housing 132, a first shutting member 134, and a first door 136. The housing 132 is disposed adjacent to the vaporizer installing portion 112 and defines a space in which the organic vaporizer 124 waits. The housing 132 is sealed from the outside to prevent the organic vaporizer 124 from being contaminated by external contaminants. A transparent window is formed at one side of the standby chamber 130, enabling an operator to recognize an internal state of the standby chamber 130 from the outside.

The first shutting member 134 opens and closes an inlet 132a formed between the vaporizer installing portion 112 and the housing 132. The inlet 132a is a passage configured for allowing the organic vaporizer 124 to travel from the standby chamber 130 into the deposition chamber 110. The first shutting member 134 may be a gate valve or a slit door. The first shutting member 134 operates by means a shutting member driver (not shown) disposed at one side of the deposition chamber 110.

The first door 136 opens and closes an entrance 132b provided to lead the organic vaporizer 124 into the standby chamber 130. The first door 136 is opened and closed by operator's hand(s). When the operator leads the organic vaporizer 124 into the standby chamber 130, the entrance 132b is fully sealed by the first door 136 and an inner pressure of the standby chamber 130 drops to a preset pressure. The first door 136 is not limited to limited to the description herein and may operate automatically by means of the controller 180 which will be described in detail later. Instead of the first door 136, a cover may be installed to seal the entrance 132b.

Similar to the standby chamber 130, the take-out chamber 140 includes a housing 142, a first shutting member 144, and a second door 146. The housing 142 is disposed adjacent to the vaporizer installing portion 112 and defines a space in which an organic vaporizer is taken out when the use of the organic vaporizer is ended inside the deposition chamber 110. The housing 142 is manufactured to be sealed from the outside. Accordingly, the organic vaporizer taken out of the housing 142 is not contaminated by external contaminants. Since the taken-out organic vaporizer is heated at a high temperature, an inner wall of the housing 142 is made of a material having a superior heatproof property. A transparent window is formed at one side of the take-out chamber 140, enabling an operator to recognize an internal state of the take-out chamber 140 from the outside.

The second shutting member 144 opens and closes an outlet 142a formed between the vaporizer installing portion 112 and the housing 142. The outlet 142a is a passage configured for allowing the organic vaporizer 124 to travel from the take-out chamber 140 into the deposition chamber 110. The second shutting member 144 may be a gate valve or a slit door. The second shutting member 144 operates by means the shutting member driver disposed at one side of the deposition chamber 110.

The second door 146 opens and closes an exit 142b provided to takes out the organic vaporizer 124 to the outside of the take-out chamber 140. When an operator takes out the organic vaporizer 124 to the take-out chamber 130, the exit 142b is fully sealed by the second door 146 and an inner pressure of the take-out chamber 140 drops. The second door 146 is not limited to limited to the description herein and may operate automatically by means of the controller 180 which will be described in detail later. Instead of the second door 146, a cover may be installed to seal the exit 142b.

In this embodiment, it is recorded that a vaporizer replacing portion 150 includes two chambers, i.e., a standby chamber 130 and a take-out chamber 140. However the vaporizer replacing portion 150 may include one vaporizer exchange chamber (not shown), in which an organic vaporizer waits and is taken out, and may be configured to take out a used organic vaporizer to the outside and carry a new organic vaporizer into the deposition chamber 110. Nevertheless, it is desirable that the vaporizer replacing portion 150 has the foregoing configuration for fast replacement of an organic vaporizer.

The vaporizer transporting unit 160 includes a guide member 162 and a driver 164. The guide member 162 is manufactured to guide an organic vaporizer and may be a guide rail. For example, the organic vaporizers 122 and 124 are manufactured to travel along the guide member 162 installed at the deposition member 110. The guide member 162 is installed linearly with the deposition chamber 110, the standby chamber 130, and the take-out chamber 140, respectively. Thus the organic vaporizers 122 and 124 travels to the standby chamber 130, the vaporizer installing portion 112 of the deposition chamber 110, and the take-out chamber 140, along guide members 162, in the order named. Stoppers (not shown) may be installed at guide members 162 of the wait camber 130, the vaporizer installing portion 112, and the take-out chamber 140, respectively. Each of the stoppers may be stopped or fixed at the designated position of an organic vaporizer.

The driver 164 enables the organic vaporizers 122 and 124 to travel along the guide member 162. The driver 164 may include, for example, a motor and a plurality of gears coupled with the motor. The driver 164 is provided to the standby chamber 130 and the take-out chamber 140 to move the organic vaporizers 122 and 124. As mentioned in this embodiment, a driver 164 is installed at a standby chamber 130 and a take-out chamber 140, respectively. However, the driver 160 is variable in position, number, install method, and configuration.

The sensoring portion 170 measures a consumption of the organic vaporizer 122 disposed at the vaporizer installing portion 112. The sensoring portion 170 is disposed over the organic vaporizer 122 to sense vaporization density and amount of organic compounds vaporized from the organic vaporizer to sense the amount of organic compounds stored in the organic vaporizer 122. Further, the sensoring portion 170 may take a straight-line motion and a reciprocation motion at the upper side of a vaporization hole formed at the organic vaporizer 122. The sensoring portion 170 may be, for example, a Quartz-Crystal Microbalance(QCM) equipment, which measures the change of the oscillating frequency of a micro structure (wherein the change of the oscillating frequency of a microstructure results from increase in mass of the microstructure) and senses a mass of the micro structure from the change in frequency, i.e., using a mass micro-balancing technique.

According to another embodiment, the sensoring portion 170 may measure a weight of the organic vaporizer 122 to sense a consumption of organic compounds of the organic vaporizer 122. The sensoring portion 170 may measure a load of a specific object such as a load cell. That is, the sensoring portion 170 is manufactured to measure a load of the organic vaporizer 122 and a controller 180, which will be described in detail later, controls the sensoring portion 170 to replace the organic vaporizer 122 when a load of the organic vaporizer 122 from the sensoring portion 170 is smaller than a preset load. The sensoring portion 170 is provided with various manners and configurations to the amount of organic compounds stored or used in the organic vaporizer 122.

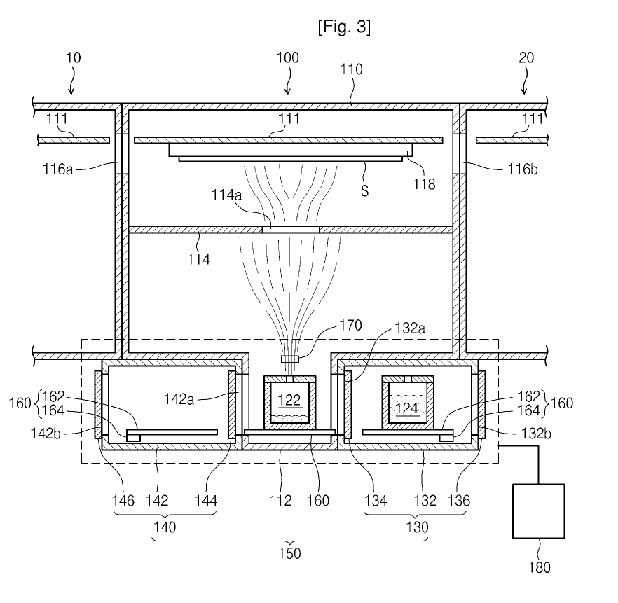

The controller 180 controls the vaporizer replacing portion 150, the vaporizer transporting unit 160, and the sensoring portion 170. The controller 180 receives data on the amount of organic compounds used in the organic vaporizer 122 from the sensoring portion 170 to judge timing to replace the organic vaporizer 122. When the controller 180 decides to replace the organic vaporizer 122, the organic vaporizer 122 is taken out to the take-out chamber 140 and controls the vaporizer replace portion 150 and the vaporizer transporting unit 160 to carry an organic vaporizer 124 in the deposition chamber 110. The organic vaporizer 124 transported to the deposition chamber 110 vaporizes organic compounds by heating the same and deposits the vaporized organic compounds on a surface of a substrate S. The controller 180 will be described in detail later with reference to FIG. 3 through FIG. 7.

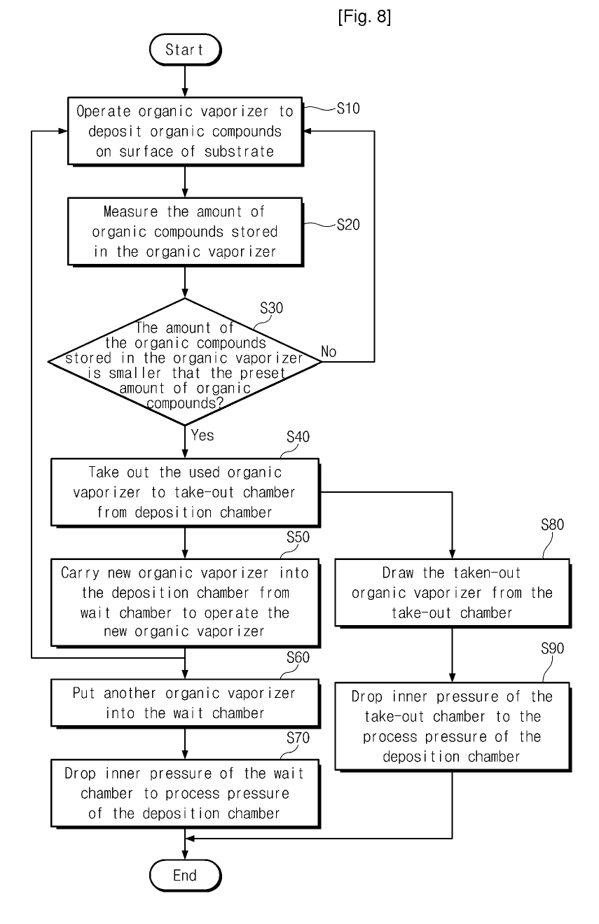

The operation steps and effect of the above-described deposition apparatus 100 will now be described in detail. FIG. 3 through FIG. 7 are diagram illustrating the operation and effect of the apparatus for depositing organic compounds shown in FIG. 2, and FIG. 8 is a flowchart illustrating a method for depositing organic compounds according to the present invention.

Referring to FIG. 8, when deposition of organic compounds is started, a substrate is accommodated in a deposition chamber 110 and an organic vaporizer 122 vaporizes the organic compounds to deposit the vaporized organic compounds on a deposition surface of a substrate S (S10). That is, referring to FIG. 3, the inside of the deposition chamber 110 is maintained at a high vacuum state and a substrate S is carried into the deposition chamber 110 through a substrate entrance 116a at a constant speed. A mask attaching apparatus 10 attaches a predetermined pattern-formed mask (not shown) to a bottom surface of the substrate S before the substrate S travels to the deposition chamber 110. The deposition chamber 110 forms thin films from the front end to the rear end of the substrate S using the pattern- formed mask. When the substrate S is carried into the deposition chamber 110, the organic vaporizer 122 heats and vaporizes organic compounds. The organic compounds vaporized from the organic vaporizer 122 pass a blocking plate 114. The organic compounds passing the blocking plate 114 are distributed and deposited on the substrate S traveling at a constant speed. Such deposition steps are repeatedly performed.

While the deposition is conducted, a controller 180 measures the amount of organic compounds in the organic vaporizer 122 (S20). That is, a sensoring portion 170 measures the amount of the organic compounds vaporized from the organic vaporized 122 and transmits data about the amount of the vaporized organic compounds to the controller 180. The controller 180 receives the data to determine whether the amount of the organic compounds stored in the organic vaporizer 122 is smaller than a preset stored amount (S30). For example, in the case where the amount of the organic compounds in the organic vaporizer 122 is smaller than a preset stored amount, the amount of the organic compounds vaporized from the organic vaporizer 122 is reduced. In the case where the amount of vaporized organic compound measured by the sensoring portion 170 is smaller than the preset amount of organic compounds vaporized, the controller 180 takes a replacement of the organic vaporizer 122.

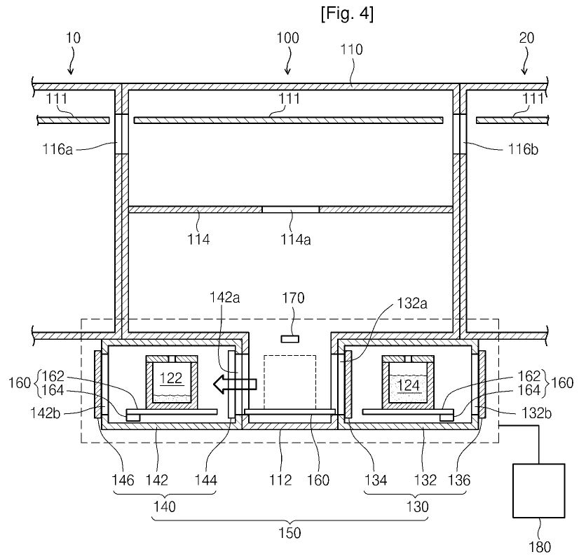

In the case where the amount of the organic compounds in the organic vaporizer 122 is smaller than a preset amount, the controller 180 takes a used organic vaporizer 122 out of the deposition chamber 110 and carries the taken organic vaporizer 122 to a take-out chamber 140 (S40). That is, referring to FIG. 4, the controller 180 controls a second shutting member 144 of the take-out chamber 140 to open an outlet 142a when the replacement of the organic vaporizer 122 is started. Before the second shutting member 144 is opened, it is desirable to adjust an inner pressure of the take-out chamber 140 to be same as that of the deposition chamber 10.

When the outlet 142a is opened, the controller 180 controls a guide member 160 to deliver the organic vaporizer 122 to the take-out chamber 140 from the deposition chamber 110. When the organic vaporizer 122 is delivered to the take-out chamber 140, the controller 180 closes the second shutting member 144. Since the organic vaporizer 122 delivered to the take-out chamber 140 is heated at a high temperature, it is required that the organic vaporizer 122 is cooled for a predetermined time in the take-out chamber 140. For example, the organic vaporizer 122 may be cooled using cooling means, such as a fan or a cooling gas supply unit, provided to the take-out chamber 140 or may be cooled naturally until a temperature of the organic vaporizer drops to a predetermined temperature.

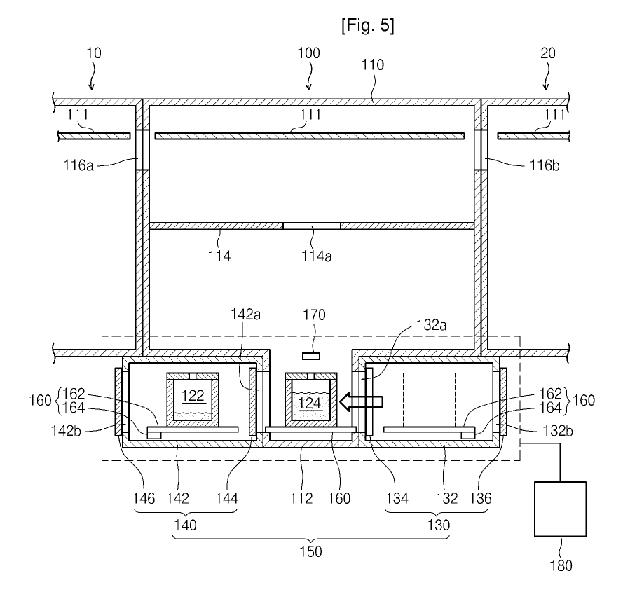

When the organic vaporizer 122 is delivered to the take-out chamber 140, the controller 180 carries a new organic vaporizer 124 into a deposition chamber 110 from a standby chamber 130 to operate the new organic vaporizer 124 (S50). That is, referring to FIG. 5, the controller 180 controls a first shutting member 134 to open an inlet 132a. Before the shutting member 134 is opened, it is desirable to adjust an inner pressure of the standby chamber 130 to be same as that of the deposition chamber 110. When the inlet 142a is opened, the controller 180 controls the guide member 160 to deliver the organic vaporizer 124 to the deposition chamber 110 from the standby chamber 130. When the organic vaporizer 124 is delivered to the deposition chamber 110, the controller 180 operates the organic vaporizer 124. The organic vaporizer 124 vaporizes organic compounds to perform a deposition process.

If the deposition process is performed by means of the new organic vaporizer 124, the controller 180 carries another organic vaporizer into the standby chamber 130 (S60). When the organic vaporizer is carried into the standby chamber 130, an inner pressure of the standby chamber 130 drops to a process pressure of the deposition chamber 110 (S70). As described in this embodiment, the organic vaporizer 122 and another organic vaporizer are used. However, organic vaporizers are variable in number.

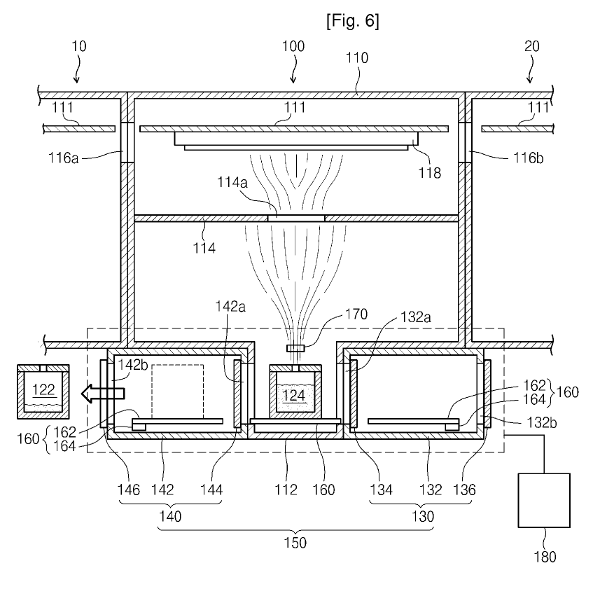

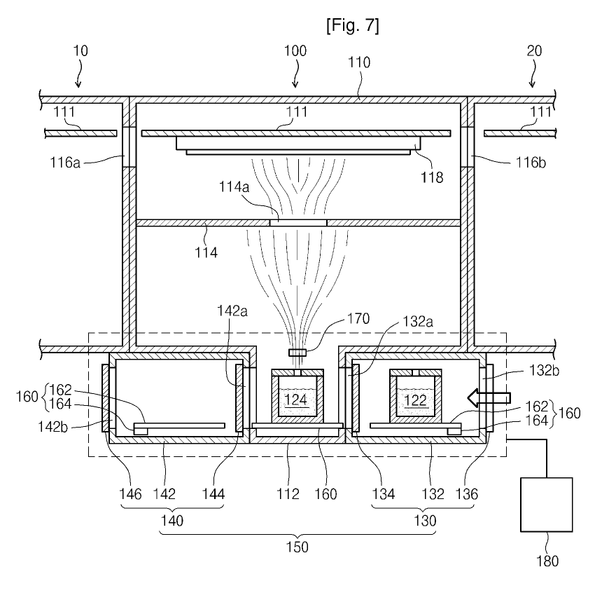

That is, referring to FIG. 6, when the organic vaporizer 122 delivered to the take-out chamber 140 in the S40 is cooled to the normal temperature, it is taken out of the take-out chamber 140 (S80). When the organic vaporizer 122 is taken out of the take-out chamber 140, the controller drops the inner pressure of the take-out chamber 140 to a process pressure of the deposition chamber 110 (S90). This is done to prevent the process pressure of the deposition chamber 110 from changing due to the mismatch between the inner pressures of the deposition chamber 110 and the take-out chamber 140 when the organic vaporizer 122 used in the deposition chamber 110 is replaced. An operator refills the taken-out organic vaporizer 122 with organic compounds. Referring to FIG. 7, the operator carries the refilled organic vaporizer 122 into the standby chamber 130. When the refilled organic vaporizer 122 is carried into the wait camber 130, the inner pressure of the standby chamber 130 drops to match the inner pressure of the deposition chamber 110. This is done to prevent the process pressure of the deposition chamber 110 from changing due to the mismatch between the inner pressures of the deposition chamber 110 and the standby chamber 130 when the refilled organic vaporizer 122 is delivered into the deposition chamber 110.

As described above, organic vaporizes are replaced automatically and successively to reduce the duration in which a deposition process of organic compounds is stopped due to the replacement of an organic vaporizer. Thus, the maintenance cost decreases when an operator replaces organic vaporizes.

Although the embodiments of the present invention have been described in the context of an apparatus for depositing thin films on a substrate for use in an electro-luminescent light emitting device, it will be understood that the present invention is not limited to the description of the specification. Accordingly, the substrate may be another kind of substrate for use in manufacturing flat panel displays and the process may also be another process. Moreover, many modifications, changes, and alternatives of the invention may be made without departing from the spirit and the scope of the invention. For example, porous plates described in the embodiment are variable in material, arrangement, shape, number and so forth.

### INDUSTRIAL APPLICABILITY

The present invention may be applied to all substrate treating systems. Especially, apparatus and method for depositing organic compounds and a substrate treating system according to the present invention are applied to an apparatus for vaporizing organic compounds to deposit organic thin films on a substrate. Thus, an organic vaporizer for vaporizing organic compounds can be replaced automatically.

1. An apparatus for depositing organic compounds on a substrate, comprising a deposition chamber; a support member provided inside the deposition chamber and supporting the substrate to make a deposition surface of the substrate face downwardly; a vaporizer installing portion in which an organic vaporizer is installed to vaporize organic compounds to the deposition surface of the substrate; and
a vaporizer replacing portion disposed adjacent to the vaporizer installing portion to replace the organic vaporizer.

2. The apparatus of claim 1, further comprising: a vaporizer transporting unit configured to transport the organic vaporizer between the vaporizer installing portion and the vaporizer replacing portion.

3. The apparatus of claim 2, wherein the vaporizer transporting unit comprises: a guide member configured to guide the movement of the organic vaporizer; and a driver for allowing the organic vaporizer to move along the guide member.

4. The apparatus of claim 2, wherein the vaporizer transporting unit further comprises a sensoring portion configured to measure the consumption of organic compounds in the organic vaporizer; and a controller receiving data from the sensoring portion to determine replacement timing of the organic vaporizer and controlling the vaporizer transporting unit to replace the organic vaporizer.

5. The apparatus of claim 4, wherein the sensoring portion includes at least one load cell.

6. The apparatus of claim 2, wherein the vaporizer replacing portion comprises a standby chamber, disposed at one side of the vaporizer installing portion, in which a new organic vaporizer waits; and a take-out chamber, disposed the other side of the vaporizer installing portion, of which the organic vaporizer replaced with the new organic vaporizer is taken out.

7. The apparatus of claim 6, wherein the standby chamber comprises a first shutting member configured to open and close an inlet through which the organic vaporizer is carried into the deposition chamber from the standby chamber; and wherein the take-out chamber comprises a second shutting member configured to open and close an outlet through which the organic vaporizer is taken out of the deposition chamber into the take-out chamber.

8. A method for depositing organic compounds on a substrate, comprising: measuring the amount of organic compounds stored in an organic vaporizer during a deposition process is carried out to deposit organic compounds on the substrate; and replacing the organic vaporizer with a new organic vaporizer if the amount of the organic compounds stored in the organic vaporizer is smaller than a preset amount of organic compounds, wherein the replacing the organic vaporizer comprises taking out the organic vaporizer to a vaporizer installing portion from a deposition chamber; and carrying the new organic vaporizer into the deposition chamber from the vaporizer installing portion.

9. The method of claim 8, wherein the replacing the organic vaporizer is done by taking out the organic vaporizer to a take-out chamber disposed adjacent to the deposition chamber and carrying the new organic chamber into the deposition chamber from a standby chamber in which the new organic vaporizer waits.

10. The method of claim 8, wherein the taking out the organic vaporizer to the take-out chamber from the deposition chamber comprises adjusting an inner pressure of the take-out chamber to be same as a process pressure of the deposition chamber; opening the first shutting member configured to open and close an outlet through which the organic vaporizer is transported between the deposition chamber and the take-out chamber;
transporting the organic vaporizer to the take-out chamber from the deposition chamber; and
closing the first shutting member.

11. The method of claim 9, wherein the carrying the organic vaporizer into the deposition chamber from the standby chamber comprises adjusting an inner pressure of the standby chamber to be same as a process pressure of the deposition chamber; opening the second shutting member configured to open and close an inlet through which the organic vaporizer is transported between the standby chamber and the deposition chamber; transporting the organic vaporizer to the deposition chamber from the standby chamber; and closing the second shutting member.

12. The method of claim 10, wherein the taking out the organic vaporizer to the takeout chamber from the deposition chamber further comprises dropping the inner pressure of the take-out chamber to the process pressure of the deposition chamber when the organic vaporizer is drawn to the exterior of the take-out chamber.

13. The method of claim 11, wherein the carrying the organic vaporizer into the deposition chamber from the standby chamber comprises putting the organic vaporizer or another organic vaporizer into the standby chamber; and dropping the inner pressure of the standby chamber to a process pressure of the deposition chamber.

14. The method of claim 8, wherein the measuring the amount of organic compounds stored in the organic vaporizer is done by measuring weight change of the organic vaporizer.

15. A substrate treating system comprising a mask attaching apparatus configured to attach a pattern-formed mask to a deposition surface of a substrate; a deposition apparatus configured to deposit organic compounds on the mask attached deposition surface of the substrate; and a mask recovering apparatus configured to recover the mask from the substrate on which the organic compounds are deposited, wherein the deposition apparatus comprises: a deposition chamber; a support member provided inside the deposition chamber and supporting the substrate to make a deposition surface of the substrate face downwardly; a vaporizer installing portion in which an organic vaporizer is installed to vaporize organic compounds to the deposition surface of the substrate; a vaporizer replacing portion disposed adjacent to the vaporizer installing portion to replace the organic vaporizer; and a vaporizer transporting unit configured to transport the organic vaporizer between the vaporizer installing portion and the vaporizer replacing portion.

16. The substrate treating system of claim 15, wherein the vaporizer transporting unit further comprises: a sensoring portion configured to measure the consumption of organic compounds of the organic vaporizer; and a controller receiving data from the sensoring portion to determine replacement timing of the organic vaporizer and controlling the vaporizer transporting unit to replace the organic vaporizer.

17. The substrate treating system of claim 16, wherein the vaporizer replacing portion comprises: a standby chamber, disposed at one side of the vaporizer installing portion, in which a new organic vaporizer waits; and a take-out chamber, disposed the other side of the vaporizer installing portion, of which the new organic vaporizer is taken out.

18. The substrate treating system of claim 17, wherein the standby chamber comprises a first shutting member configured to open and close an inlet through which the organic vaporizer is carried into the deposition chamber from the standby chamber; and wherein the take-out chamber comprises a second shutting member configured to open and close an outlet through which the organic vaporizer is taken out of the deposition chamber into the take-out chamber.
